(19) United States
(12) Patent Application Publication
(10) Pub. No.: US 2014/0065547 A1
(43) Pub. Date: Mar. 6, 2014

(54) CHARGED PARTICLE BEAM APPARATUS, DRAWING APPARATUS, AND METHOD OF MANUFACTURING ARTICLE

(71) Applicant: CANON KABUSHIKI KAISHA, (US)

(72) Inventor: Keiichi Arita, Himeji-shi (JP)

(73) Assignee: CANON KABUSHIKI KAISHA, TOKYO (JP)

(21) Appl. No.: 13/717,987

(22) Filed: Dec. 18, 2012

(30) Foreign Application Priority Data
Dec. 28, 2011 (JP) 2011-289886

(51) Int. Cl. H01J 37/317

(52) U.S. Cl. CPC H01J 37/3177
USPC 430/296; 250/492.3

(57) ABSTRACT

An apparatus includes: an image sensor including pixels which constitute rows; and a controller configured to control an irradiation operation of irradiating a pixel of the image sensor with a charged particle beam to generate a signal charge, a transfer operation of sequentially transferring, pixel by pixel in a column direction, the signal charge accumulated in the irradiated pixel, and an output operation of outputting the transferred signal charge from the image sensor. The controller is configured to cause a first irradiation operation for a first part of the rows as an irradiated region, a transfer operation of transferring a signal charge generated in the first part to a second part of the rows adjacent to the first part, as a non-irradiated region, and a second irradiation operation for the first part, to be performed sequentially.

### BACKGROUND OF THE INVENTION

1. Field of the Invention

The present invention relates to a charged particle beam apparatus, a drawing apparatus, and a method of manufacturing an article.

2. Description of the Related Art

In a drawing apparatus which uses a plurality of electron beams, it is necessary to periodically measure and correct the characteristics of the electron beams in order to reduce the influence of variations and temporal changes in characteristics of the electron beams. The characteristics of each electron beam to be measured include, for example, the intensity, irradiation position, and focus of this electron beam. The number of electron beams to be measured varies depending on the characteristics to be measured. When, for example, the intensity of each electron beam is to be corrected, all electron beams must be measured because a blanker to be corrected (blanking deflector) is set for each electron beam. On the other hand, when one correction system for the irradiation position and focus of each electron beam is set for all electron beams or a plurality of electron beams, these characteristics are corrected using a plurality of electron beams at once. It is therefore only necessary to measure the characteristics of, for example, some of a plurality of electron beams as representatives in order to correct the irradiation positions and focuses of these electron beams, and obtain the average of the measured characteristics.

When a two-dimensional array of electron beams is to be measured, a method which uses a CCD area sensor including pixels in the same array as that of electron beams is available. This configuration is efficient because all electron beams can be measured at once. However, when only representative points are to be measured, unnecessary pixel data transfer must be performed a number of times corresponding to the measurement count, and hinders the shortening of the measurement time. Japanese Patent Laid-Open No. 2000-209599 proposes a method of omitting transfer of data of any unnecessary vertical CCD column to reduce the amount of data, thereby speeding up a read operation without raising the transfer speed of horizontal CCDs. Also, Japanese Patent Laid-Open No. 2004-289539 proposes a method of implementing a plurality of charge accumulation units using interline transfer CCDs, as a means for increasing the number of electron beams that can be measured at once. In addition, a method of independently implementing global measurement and local measurement sensors, and a method of arranging a plurality of line sensors in place of area sensors, and driving only necessary sensors have been proposed.

In the technique described in Japanese Patent Laid-Open No. 2000-209599, when unnecessary data are aligned vertically, the size of data to be transferred can be reduced, so the read time can be shortened. However, when unnecessary data are aligned horizontally, only necessary vertical CCD columns are present, so the read time cannot be shortened. In the technique described in Japanese Patent Laid-Open No. 2004-289539, since the number of charge accumulation units is increased to increase the number of electron beams that can be measured at once, the read count can be reduced. This, however, complicates the sensor structure, and makes it necessary to read charges accumulated in all pixels, thus producing only a little effect of shortening the time. When a plurality of sensors are arranged, and signals are output from only sensors irradiated with electron beams, the frequency of read of unnecessary pixels, which poses a problem in an area sensor, reduces, thus shortening the measurement time. Nevertheless, this arrangement is disadvantageous in terms of footprint and cost as, for example, the area in which sensors are arranged increases, or an external circuit must be set for each sensor.

### SUMMARY OF THE INVENTION

The present invention provides, for example, a technique advantageous in terms of efficient measuring of characteristics of charged particle beams.

The present invention provides a charged particle beam apparatus which processes an object with a plurality of charged particle beams, the apparatus comprising: an image sensor including pixels which constitute a plurality of rows; and a controller configured to control an irradiation operation of irradiating a pixel of the image sensor with a charged particle beam to generate a signal charge, a transfer operation of sequentially transferring, pixel by pixel in a column direction, the signal charge accumulated in the irradiated pixel, and an output operation of outputting the transferred signal charge from the image sensor, wherein the controller is configured to cause a first irradiation operation for a first part of the plurality of rows as an irradiated region, a transfer operation of transferring a signal charge generated in the first part by the first irradiation operation to a second part of the plurality of rows, which is adjacent to the first part, as a non-irradiated region, and a second irradiation operation for the first part, to be performed sequentially.

Further features of the present invention will become apparent from the following description of exemplary embodiments with reference to the attached drawings.

### BRIEF DESCRIPTION OF THE DRAWINGS

FIG. 1 is a schematic view showing the configuration of an electron beam drawing apparatus;

FIG. 2 shows views for explaining irradiated regions;

FIG. 3 shows views for explaining a transfer operation;

FIG. 4 shows views for explaining how to select an irradiated region;

FIG. 5 shows views for explaining how to select an irradiated region;

FIG. 6 shows views for explaining pixels for measuring characteristics, and pixels for detecting errors;

FIG. 7 is a partial enlarged view for explaining knife edge measurement according to the fifth embodiment; and

FIGS. 8A to 8E are graphs showing the results of knife edge measurement according to the fifth embodiment.

### DESCRIPTION OF THE EMBODIMENTS

Although the present invention is applicable to a charged particle beam apparatus which performs various types of processing (for example, drawing, machining, measurement, and inspection) of an object using a plurality of charged particle beams, an example in which the present invention is applied to a drawing apparatus which draws on a substrate using a plurality of electron beams will be described hereinafter.

### First Embodiment

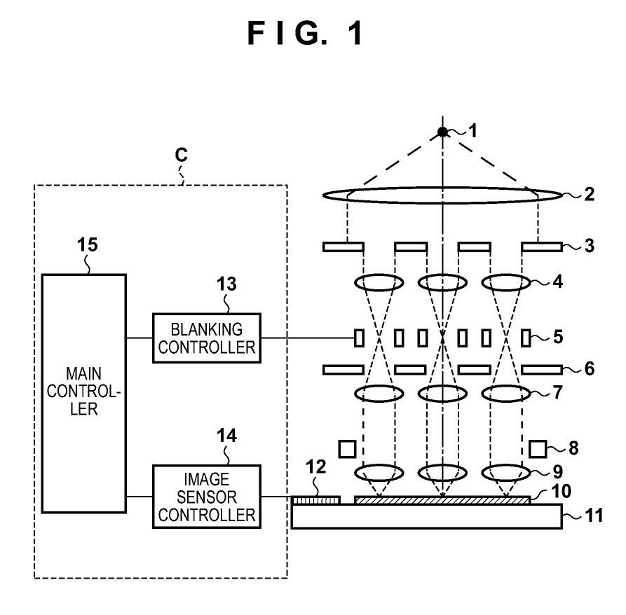

The configuration of a multibeam electron beam drawing apparatus according to the first embodiment will be described with reference to a schematic view shown in FIG. 1. Using a crossover 1 formed by an electron gun as an electron beam source, a collimated electron beam is generated by a condenser lens 2. An aperture array 3 is formed by two-dimensionally arraying apertures. A lens array 4 is formed by two-dimensionally arraying electrostatic lenses having the same focal length. A blanker array 5 is formed by two-dimensionally arraying blankers capable of individually deflecting electron beams. The number of electron beams to be guided to a stage 11 in parallel is determined by making a blanking controller 13 control the blanker array 5. The collimated electron beam generated by the condenser lens 2 is split into a plurality of electron beams by the aperture array 3. The split electron beams form intermediate images of the crossover 1 at the level (within the plane) of the blanker array 5 via the lens array 4.

The electron beams having passed through the blanker array 5 are guided via electron lenses 7 and 9 onto a substrate 10 or CCD area sensor (image sensor) 12 set on the stage 11. The CCD area sensor 12 includes pixels arranged on pluralities of rows and columns. The irradiation position of each electron beam is determined based on the amount of deflection by a deflector 8. The CCD area sensor 12 detects the guided electron beams under the control of an image sensor controller 14. Electron beams detected to measure their characteristics are set by a main controller 15, and selected by driving the blanker array 5 by the blanking controller 13. Data of the electron beams detected by the CCD area sensor 12 are sent to the main controller 15 to obtain the characteristics of these electron beams. The characteristics of each electron beam include, for example, the intensity, intensity distribution, and irradiation position of this electron beam.

A controller C including the main controller 15 and image sensor controller 14 controls an irradiation operation of charged particle beams, a transfer operation of sequentially transferring signal charges for each pixel in the column direction, and an output operation of the signal charges. In the irradiation operation, pixels are irradiated with charged particle beams to generate signal charges in the pixels. In the transfer operation, the signal charges accumulated in the pixels are sequentially transferred for each pixel in the column direction. In the output operation, the signal charges accumulated in the pixels are output from the image sensor.

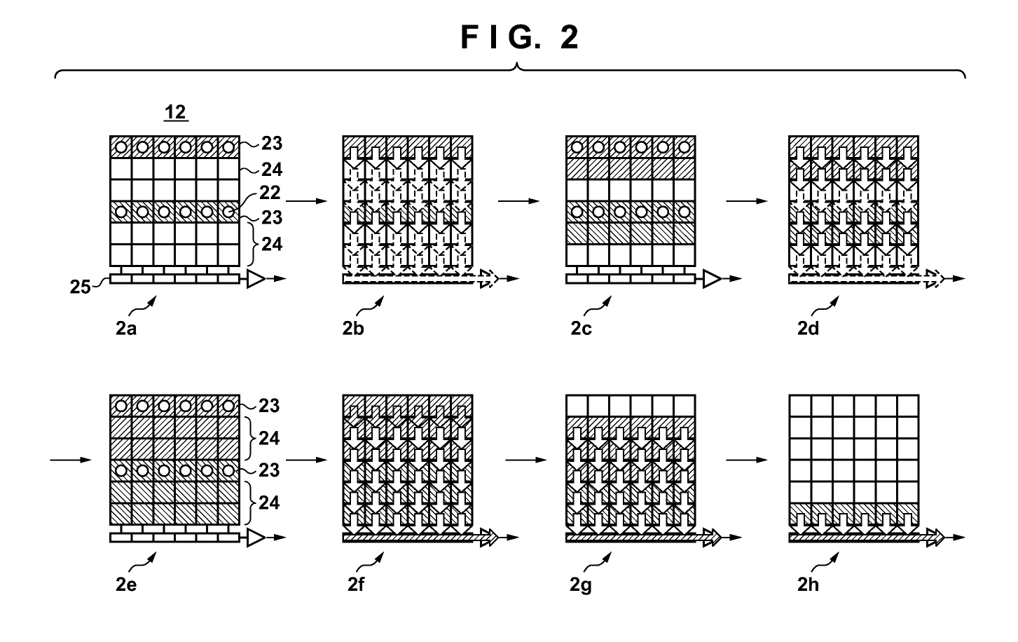

Generation, transfer, and output of signal charges according to the first embodiment will be described with reference to FIG. 2. Referring to FIG. 2, pixels on the first and fourth rows serve as pixels in an irradiated region 23 to be irradiated with some electron beams 22 to measure their characteristics. Also, pixels on the second, third, fifth, and sixth rows serve as pixels in a non-irradiated region that is not to be irradiated with any electron beams. A non-irradiated region is set adjacent to the irradiated region in the direction in which signal charges are transferred. First, in a first irradiation operation, the irradiated region (first certain rows) 23 is irradiated with the electron beams 22 to be measured to generate and accumulate signal charges in the pixels of the irradiated region 23 (state 2a). A transfer operation is then performed in synchronism with a vertical transfer clock (state 2b), and the signal charges accumulated in the pixels of the irradiated region 23 on one row are transferred to pixels in a non-irradiated region (second certain rows) 24, so the pixels in the irradiated region 23 have no signal charges accumulated in them (state 2b). A second irradiation operation is then performed in the irradiated region (first certain rows) 23 having no signal charges accumulated in it (state 2c). Thereafter, a transfer operation and an irradiation operation are sequentially performed until no pixel remains without accumulating a signal charge in the non-irradiated region 24 (states 2d and 2e). When no pixel remains without accumulating a signal charge in the non-irradiated region 24, the signal charges accumulated in the irradiated region 23 and non-irradiated region 24 are sequentially output using horizontal CCDs 25 (states 2f to 2h). In the first embodiment, even when only some pixels of the CCD area sensor 12 are measured as the irradiated region 23, signal charges can be output without any wasteful transfer operation (for example, an output operation for each irradiation operation).

### Second Embodiment

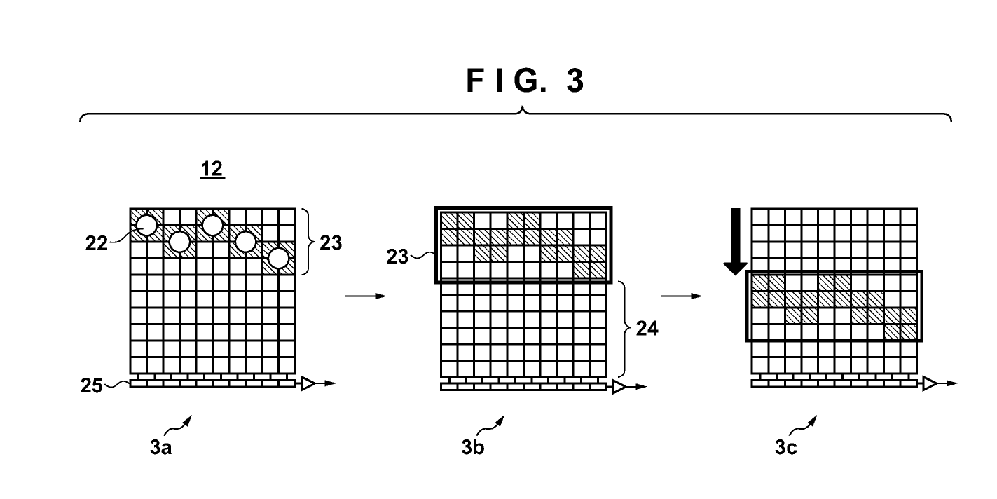

The second embodiment in which the relationship between the electron beam irradiation operation and transfer operation is determined will be described with reference to FIG. 3. In the second embodiment, the arrangement of electron beams 22 having characteristics to be measured has a shift in the transfer direction (vertical direction), as indicated by hatched regions in a state 3a shown in FIG. 3. In this case, an irradiated region 23 is set to four rows including the hatched regions. First, a plurality of pixels indicated by the hatched regions in the irradiated region 23 are irradiated with the electron beams 22, so signal charges are accumulated in the plurality of pixels (state 3b). Transfer operations are repeated a number of times (four times) corresponding to the number of rows in the irradiated region 23 to obtain a state in which no signal charges are accumulated in the pixels of the irradiated region 23 (state 3c). After the second irradiation operation is performed for each pixel indicated by the hatched region in the irradiated region 23, a transfer operation and output operation are performed. In the second embodiment, a main controller 15 obtains the number of rows in the irradiated region 23 from the arrangement of electron beams 22 having characteristics to be measured and, eventually, the number of transfer operations to be performed after a first irradiation operation.

### Third Embodiment

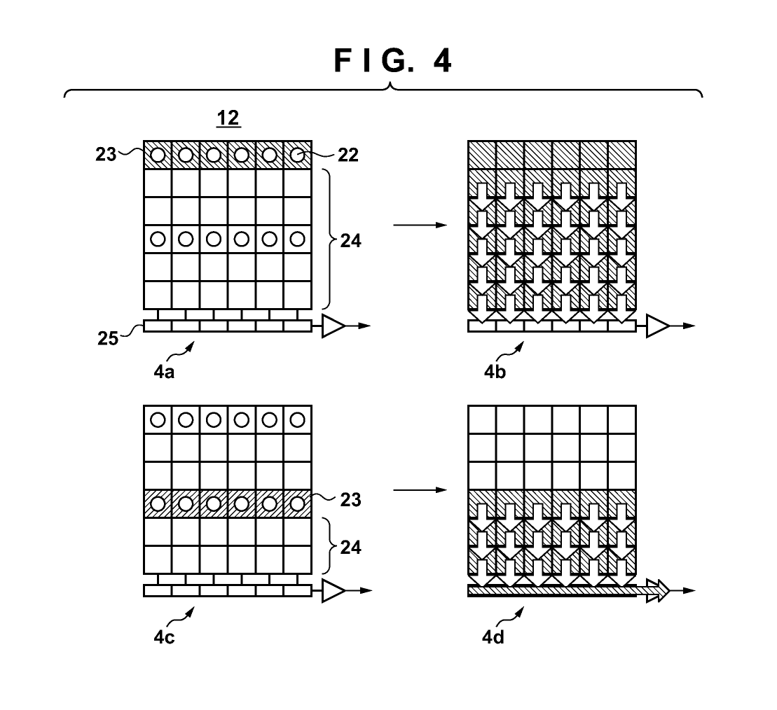

The third embodiment in which an irradiated region 23 is set from an array of electron beams 22 to be measured will be described with reference to FIG. 4. A CCD area sensor 12 includes 6 (rows)×6 (columns)=36 pixels. Assume herein that six irradiation operations are necessary to measure the characteristics of electron beams 22 on one row and six columns. In this case, the irradiated region 23 is set to pixels on the first row, as indicated by a state 4a shown in FIG. 4. A first irradiation operation, a transfer operation, a second irradiation operation, . . . , a sixth irradiation operation are performed to accumulate signal charges in all pixels on six rows and six columns (state 4b), and an output operation is then performed.

On the other hand, assume that three irradiation operations are necessary to measure the characteristics of electron beams 22 on one row and six columns. In this case, the irradiated region 23 is set to pixels on the fourth row (state 4c). A first irradiation operation, a transfer operation, . . . , a third irradiation operation are performed to accumulate signal charges in pixels on three lower rows (state 4d), and an output operation is then performed. Although a CCD area sensor 12 including 6 (rows)×6 (columns)=36 pixels is used as an example herein, the number of pixels of the CCD area sensor 12 is not limited to this example, and the structure of the CCD area sensor 12 may vary depending on the measurement conditions. In any case, even if the array of electron beams 22 having characteristics to be measured varies, the throughput can be prevented from degrading due to wasteful transfer operations.

### Fourth Embodiment

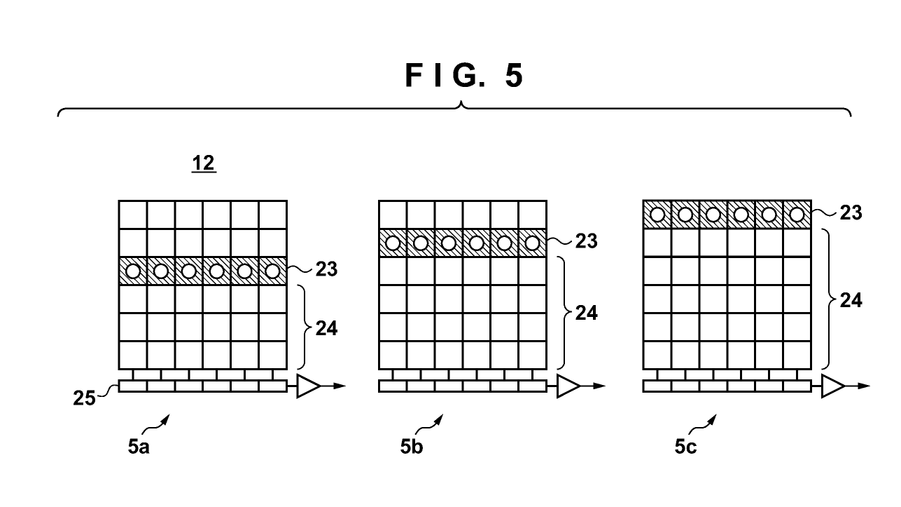

The fourth embodiment in which an irradiated region 23 is set from an array of electron beams 22 to be measured will be described with reference to FIG. 5. When an arbitrary position on a CCD area sensor 12 is irradiated with an electron beam, a main controller 15 counts and records the irradiation time. The case wherein one measurement operation is performed upon four irradiation operations will be considered as an example herein. First, the main controller 15 obtains the number of vertical transfer operations allotted for one measurement operation from the required throughput. Assume, for example, that the time allotted for measurement is 13 msec, the time taken for one irradiation operation is 1 msec, and the time taken for one transfer operation is 1 msec. In this case, regardless of whether the irradiated region 23 is set to a state 5a, 5b, or 5c shown in FIG. 5, it takes 7 msec to complete first to third irradiation operations, and a fourth irradiation operation upon one transfer operation subsequent to each irradiation operation. Therefore, 6 msec is available to transfer the signal charges accumulated in the irradiated region 23 and a non-irradiated region 24 after the fourth irradiation operation.

However, if the irradiated region 23 is set to the state 5a shown in FIG. 5, it takes 4 msec to transfer the signal charges accumulated in the irradiated region 23 and non-irradiated region 24 after the fourth irradiation operation. If the irradiated region 23 is set to the state 5b shown in FIG. 5, it takes 5 msec to transfer the signal charges accumulated in the irradiated region 23 and non-irradiated region 24 after the fourth irradiation operation. If the irradiated region 23 is set to the state 5c shown in FIG. 5, it takes 6 msec to transfer the signal charges accumulated in the irradiated region 23 and non-irradiated region 24 after the fourth irradiation operation. That is, regardless of whether the irradiated region 23 is set to the state 5a, 5b, or 5c in FIG. 5, it is possible to perform a measurement process which satisfies the required throughput. Nevertheless, when the irradiated region 23 is set to the state 5a shown in FIG. 5, the time taken for measurement can be reduced. Also, when the irradiated region 23 is set by sequentially switching between a plurality of different irradiated regions 23 in the states 5a to 5c shown in FIG. 5, this setting operation can be advantageous in terms of avoiding significant degradation in sensitivity of pixels on specific rows of the CCD area sensor 12 while satisfying the throughput specification.

### Fifth Embodiment

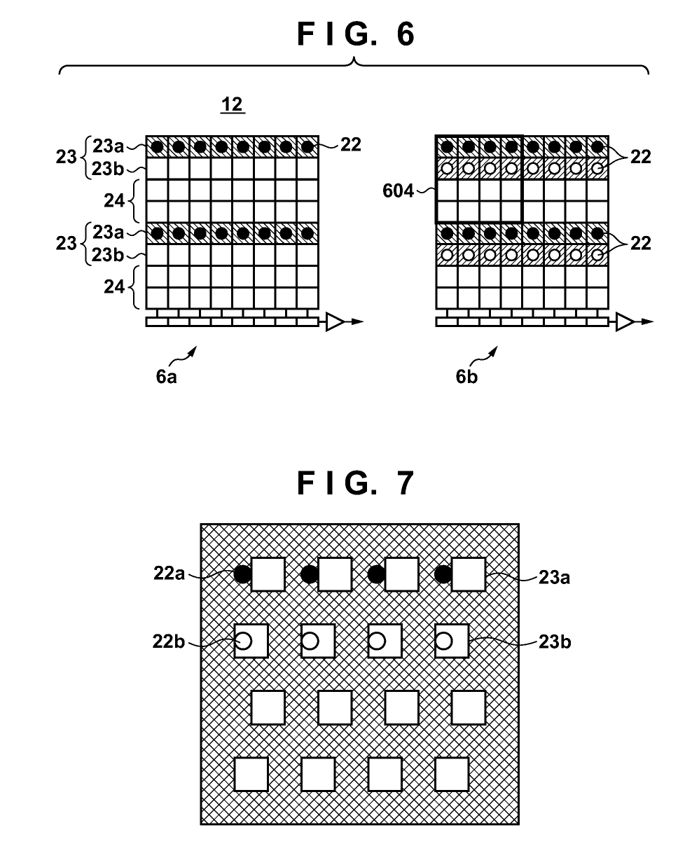

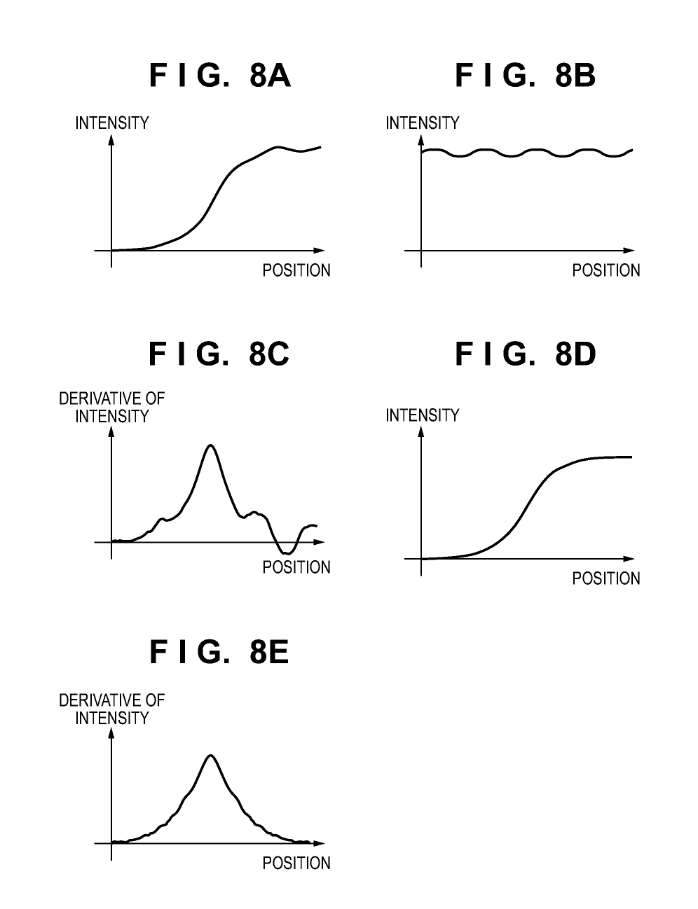

The fifth embodiment in which an irradiated region 23 includes first pixels to be irradiated with electron beams having characteristics to be measured, and second pixels used to obtain correction values will be described with reference to FIG. 6. Pixels in a hatched region 23a in 6a of FIG. 6 serve as first pixels, and pixels in a region 23b serve as second pixels. Pixels adjacent to the first pixels in the transfer direction, for example, are selected as the second pixels. In addition to knife edge measurement of electron beams 22a in the first pixels of the region 23a, the intensities of electron beams 22b are measured in the second pixels of the region 23b. FIG. 7 is a partial enlarged view of the CCD area sensor 12 shown in FIG. 6. Since the S/N ratio is low in the portions of the electron beams, in which the intensity is low, the electron beams are measured at as high an intensity as possible. Hence, to obtain correction values using the second pixels, knife edges which measure the electron beams 22b are set at positions spaced apart from knife edges which measure the electron beams 22a by a distance equal to or larger than the diameter of each electron beam. This prevents the electron beams 22b from traversing the knife edges while the electron beams 22a are measured upon traversing the knife edges. FIGS. 8A to 8E show the measurement results obtained by the above-mentioned configuration. FIG. 8A shows the knife edge measurement result of the electron beam 22a in the first pixel, and FIG. 8B shows the knife edge measurement result of the electron beam 22b in the second pixel. FIG. 8A shows the position on the abscissa, and the intensity on the ordinate. As shown in FIG. 8B, if the intensity of the electron beam has a temporal variation (fluctuation), the fluctuation influences the knife edge measurement result. Therefore, the intensity distribution of the electron beam calculated by differentiating a function represented by the graph shown in FIG. 8A distorts, as shown in FIG. 8C. When the result (the influence of the intensity fluctuation) shown in FIG. 8B is subtracted from the result shown in FIG. 8A to remove the influence of the fluctuation, a measurement result as shown in FIG. 8D is obtained, and its derivative is as shown in FIG. 8E. Such a correction operation is advantageous in terms of measurement precision and accuracy. The influence of the fluctuation can be removed by, for example, normalizing an intensity measurement result, and dividing a knife edge measurement result by the normalization result. Although a correction value is obtained by taking into consideration a fluctuation in intensity of the electron beam in the above-mentioned embodiment, the present invention is not limited to this. A dark current value obtained by preventing the second pixel from being irradiated with the electron beam, for example, may be taken into consideration. The use of the above-mentioned measurement method is advantageous in terms of reducing the influence of a fluctuation in intensity of the electron beam and noise generated by the CCD area sensor 12.

Embodiments of the present invention have been described by taking, as an example, a drawing apparatus which draws on a substrate with a plurality of charged particle beams. However, the present invention is applicable not only to a drawing apparatus but also to other charged particle beam apparatuses which use a plurality of charged particle beams, such as an electron microscope and an electronic distance measuring apparatus.

[Method of Manufacturing Article]

A method of manufacturing an article according to a preferred embodiment of the present invention is suitable for manufacturing various articles including a microdevice such as a semiconductor device and a mask (reticle) for semiconductor exposure. This method can include a step of drawing a pattern on a substrate (a substrate coated with a photosensitive agent) 10 using the above-mentioned drawing apparatus or charged particle beam apparatus, and a step of developing the substrate 10 having the pattern formed on it in the drawing step. This method can also include subsequent known steps (for example, oxidation, film formation, vapor deposition, doping, planarization, etching, resist removal, dicing, bonding, and packaging). The method of manufacturing an article according to this embodiment is more advantageous in terms of at least one of the performance, quality, productivity, and manufacturing cost of an article than the conventional methods.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-289886 filed Dec. 28, 2011, which is hereby incorporated by reference herein in its entirety.

What is claimed is:

1. A charged particle beam apparatus which processes an object with a plurality of charged particle beams, the apparatus comprising:
an image sensor including pixels which constitute a plurality of rows; and
a controller configured to control an irradiation operation of irradiating a pixel of the image sensor with a charged particle beam to generate a signal charge, a transfer operation of sequentially transferring, pixel by pixel in a column direction, the signal charge accumulated in the irradiated pixel, and an output operation of outputting the transferred signal charge from the image sensor,
wherein the controller is configured to cause a first irradiation operation for a first part of the plurality of rows as an irradiated region, a transfer operation of transferring a signal charge generated in the first part by the first irradiation operation to a second part of the plurality of rows, which is adjacent to the first part, as a non-irradiated region, and a second irradiation operation for the first part, to be performed sequentially.

2. The apparatus according to claim 1, wherein
the first part includes a first pixel to be irradiated with the charged particle beam the characteristic of which is to be measured, and a second pixel used to obtain a correction value for the measurement, and
the controller is configured to obtain the characteristic based on a value of a signal charge generated by the first pixel, and a correction value obtained using the second pixel.

3. The apparatus according to claim 2, wherein the correction value includes a correction value associated with a temporal fluctuation in intensity of the charged particle beam.

4. The apparatus according to claim 2, wherein the correction value includes a dark current value of the image sensor.

5. The apparatus according to claim 1, wherein the characteristic include at least one of an intensity, an intensity distribution, and an irradiation position of the charged particle beam.

6. A drawing apparatus which performs drawing on a substrate with a plurality of charged particle beams, the apparatus comprising:
an image sensor including pixels which constitute a plurality of rows; and
a controller configured to control an irradiation operation of irradiating a pixel of the image sensor with a charged particle beam to generate a signal charge, a transfer operation of sequentially transferring, pixel by pixel in a column direction, the signal charge accumulated in the irradiated pixel, and an output operation of outputting the transferred signal charge from the image sensor,
wherein the controller is configured to cause a first irradiation operation for a first part of the plurality of rows as an irradiated region, a transfer operation of transferring a signal charge generated in the first part by the first irradiation operation to a second part of the plurality of rows, which is adjacent to the first part, as a non-irradiated region, and a second irradiation operation for the first part, to be performed sequentially.

7. A method of manufacturing an article, the method comprising:
performing drawing on a substrate using a drawing apparatus;
developing the substrate on which the drawing has been performed; and
processing the developed substrate to manufacture the article,
wherein the drawing apparatus performs the drawing on the substrate with a plurality of charged particle beams, the apparatus including:
an image sensor including pixels which constitute a plurality of rows; and
a controller configured to control an irradiation operation of irradiating a pixel of the image sensor with a charged particle beam to generate a signal charge, a transfer operation of sequentially transferring, pixel by pixel in a column direction, the signal charge accumulated in the irradiated pixel, and an output operation of outputting the transferred signal charge from the image sensor,
wherein the controller is configured to cause a first irradiation operation for a first part of the plurality of rows as an irradiated region, a transfer operation of transferring a signal charge generated in the first part by the first irradiation operation to a second part of the plurality of rows, which is adjacent to the first part, as a non-irradiated region, and a second irradiation operation for the first part, to be performed sequentially.
